(19) United States
(12) Patent Application Publication
(10) Pub. No.: US 2013/0135512 A1
(43) Pub. Date: May 30, 2013

(54) MOBILE ELECTRONIC DEVICE AND DOCKING STATION THEREOF

(71) Applicant: SAMSUNG ELECTRONICS CO., LTD., Suwon-si (KR)

(72) Inventors: Dae-myung Kim, Hwaseong-si (KR); Dong-jun Kum, Yongin-si (KR); Yun-je Oh, Seongnam-si (KR)

(73) Assignee: SAMSUNG ELECTRONICS CO., LTD., Suwon-si (KR)

(21) Appl. No.: 13/667,135

(22) Filed: Nov. 2, 2012

(30) Foreign Application Priority Data
Nov. 24, 2011 (KR) 10-2011-0123669

(51) Int. Cl. H04N 5/225; H05K 7/00

(52) U.S. Cl. 348/335; 348/375; 361/679.41; 348/E05.024

(57) ABSTRACT

A mobile electronic device including: a body including an accommodation space; and an aroma capsule that is accommodated in the accommodation space, is removable from the accommodation space, and includes an aroma to diffuse a fragrance.

### CROSS-REFERENCE TO RELATED PATENT APPLICATION

This application claims the priority benefit of Korean Patent Application No. 10-2011-0123669, filed on Nov. 24, 2011, in the Korean Intellectual Property Office, the disclosure of which is incorporated herein in its entirety by reference.

### BACKGROUND

Various embodiments relate to mobile electronic devices and docking stations thereof, and more particularly, to a mobile electronic device, which includes an aroma capsule that diffuses a fragrance, and a docking station of the mobile electronic device.

Mobile electronic devices, such as portable digital cameras, tablet computers, smart phones, and multimedia players, have been become necessary in modern times. Mobile electronic devices need to provide convenience to users as well as original functions, such as capturing images, communication, reproducing multimedia data, and the like.

Japanese utility model application publication No. 1994-084444 discloses a camera for diffusing a fragrance. This camera uses a porosity element or a fibrousness element to diffuse a fragrance. Thus, it is difficult to manage a perfume diffusing a fragrance since the perfume may leak from the camera. It is also difficult to replace the porosity element. In addition, users need to frequently confirm the amount of perfume since the users do not know a replacement time of the perfume.

### SUMMARY

Embodiments include a mobile electronic device for improving agreeableness of use by diffusing a fragrance and for providing convenience of use by controlling a light of a lighting unit.

Embodiments also include a docking station for conveniently filling an aroma capsule of the mobile electronic device and for providing additional functions, such as charging of the mobile electronic device, data communication, and data storing.

According to an embodiment, a mobile electronic device includes: a body including an accommodation space; and an aroma capsule that is accommodated in the accommodation space, is removable from the accommodation space, and includes an aroma to diffuse a fragrance.

The mobile electronic device may further include: a lighting unit that is disposed on the outside of the body and radiates light as a signal is applied thereto; and a control unit that is disposed in the body and applies the signal to the lighting unit to control the lighting unit.

The mobile electronic device may further include a timer that informs a replacement time of the aroma capsule when a predetermined time has elapsed after replacing the aroma capsule.

The control unit may control the amount of light that is radiated by the lighting unit.

The lighting unit may be formed to extend by a predetermined length along a surface of the body, and the control unit may change a length of an illumination part of the lighting unit.

The control unit may change a color of the light that is radiated by the lighting unit.

The mobile electronic device may further include a cover that is coupled to the body to cover the accommodation space.

The cover may include an opening hole of which an opening area is adjusted.

The aroma capsule may include: a container with an opening having an aroma; a rod that is inserted in the container through the opening so that a part of the rod contacts the aroma and diffuses a fragrance; and a stopper that covers the opening of the container.

The mobile electronic device may further include: a zoom lens barrel that is disposed in the body and is projected from the body, wherein the control unit changes the light of the lighting unit according to a projected length of the zoom lens barrel from the body.

The mobile electronic device may further include a sound generation unit that generates a sound, wherein the control unit controls the sound generation unit to generate a sound having a frequency of a predetermined range that insects dislike.

According to an embodiment, a docking station for a mobile electronic device includes: an aroma storage unit that stores an aroma; and an outlet that is connected to the aroma storage unit and discharges the aroma of the aroma storage unit to the outside.

The docking station may further include a hand pump device that discharges the aroma of the aroma storage unit to the outlet through a manual manipulation.

The docking station may further include an automatic pump device that discharges the aroma of the aroma storage unit to an aroma capsule through the outlet when a signal is applied to the automatic pump device after the aroma capsule is connected to the outlet.

The docking station may further include: a communication unit that communicates with the mobile electronic device; a data storage unit that stores data that is received from the mobile electronic device through the communication unit; and a station control unit that is electrically connected to the communication unit and the data storage unit and that controls the communication unit and the data storage unit.

The docking station may further include a charging unit that is electrically connected with the mobile electronic device and charges the mobile electronic device.

Embodiments of the mobile electronic device may provide agreeableness to users since a fragrance is diffused from a body thereof. In addition, embodiments of the mobile electronic device may provide convenience of use since a light of a lighting unit thereof may be controlled interacting with an operation of a zoom lens barrel or aroma capsule. In addition, by using the docking station for the mobile electronic device, it is possible to rapidly and conveniently fill the aroma capsule with an aroma and to provide information about a charging state of the mobile electronic device to the outside by controlling a light of the lighting unit during a charging of the mobile electronic device.

### BRIEF DESCRIPTION OF THE DRAWINGS

The above and other features and advantages will become more apparent by describing in detail exemplary embodiments with reference to the attached drawings in which:

FIG. 1 is a perspective view illustrating a mobile electronic device, according to an embodiment;

FIG. 2 is a block diagram illustrating components of the mobile electronic device of FIG. 1, according to an embodiment;

FIG. 3 is a side cross-sectional view illustrating a configuration of an aroma capsule that is installed in the mobile electronic device of FIG. 1, according to an embodiment;

FIG. 4 illustrates a cover that is installed in the mobile electronic device of FIG. 1, according to an embodiment;

FIG. 5 is a perspective view illustrating an example of an operation of the mobile electronic device of FIG. 1;

FIG. 6 is a perspective view illustrating another example of an operation the mobile electronic device of FIG. 1;

FIG. 7 is a side cross-sectional view illustrating a configuration of a docking station for the mobile electronic device of FIG. 1, according to an embodiment;

FIG. 8 is a side cross-sectional view illustrating an operation state of the docking station of FIG. 7, according to an embodiment;

FIG. 9 is a perspective view illustrating an example of an operation of the docking station of FIG. 7; and

FIG. 10 is a perspective view illustrating another example of an operation of the docking station of FIG. 7.

### DETAILED DESCRIPTION

Hereinafter, embodiments will be described in detail with reference to the attached drawings.

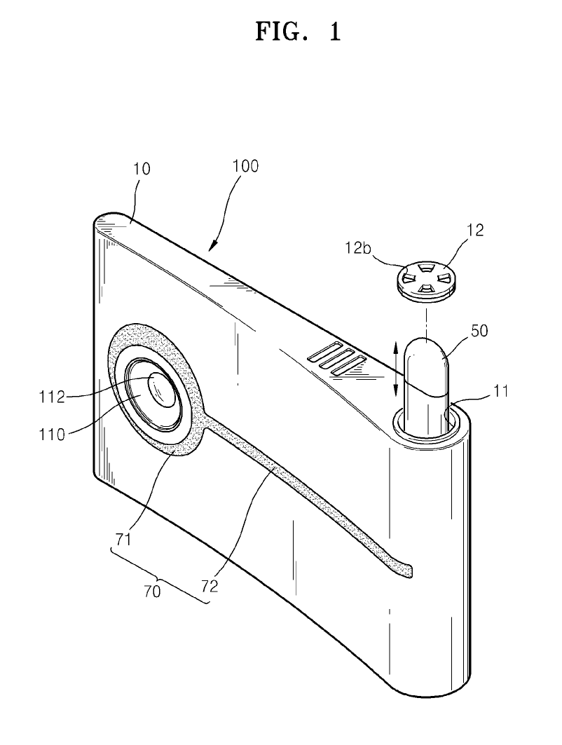

FIG. 1 is a perspective view illustrating a mobile electronic device 100, according to an embodiment.

Referring to FIG. 1, the mobile electronic device 100 includes a body 10 and an aroma capsule 50 that is installed in the body 10.

The mobile electronic device 100 is a portable digital camera for capturing a still image or a moving image, as an example. However, this should not be construed as limiting, and the mobile electronic device 100 may be formed as various kinds of portable electronic devices, such as tablet computers, laptop computers, mobile phones, smart phones, portable multimedia players, navigation devices, and the like.

The body 10 surrounds various components of the mobile electronic device 100 to protect and support the components. The body 10 includes an accommodation space 11 in which the aroma capsule 50 is accommodated.

The aroma capsule 50 diffuses a fragrance by including an aroma. The aroma capsule 50 may be accommodated in the accommodation space 11 of the body 10 and may be removed from the body 10.

After installing the aroma capsule 50 in the accommodation space 11 of the body 10, a cover 12 is installed over the accommodation space 11 of the body 10. The cover 12 supports the aroma capsule 50 to not exit from the body 10 and allows a fragrance that diffuses from the aroma capsule 50 to be emitted to the outside. For this, the cover 12 includes an opening hole 12b of which an opening area is adjusted.

A zoom lens barrel 110 is installed in front of the body 10. The zoom lens barrel 110 controls a zoom magnification for photography by including a plurality of lenses 112 and operating to project from the front of the body 10.

In addition, a lighting unit 70 is installed in front of the body 10. The lighting unit 70 radiates light as a signal is applied thereto. The lighting unit 70 includes a ring unit 71 extending along an edge of the zoom lens barrel 110, and a straight unit 72 extending from the ring unit 71 along a surface of the body 10.

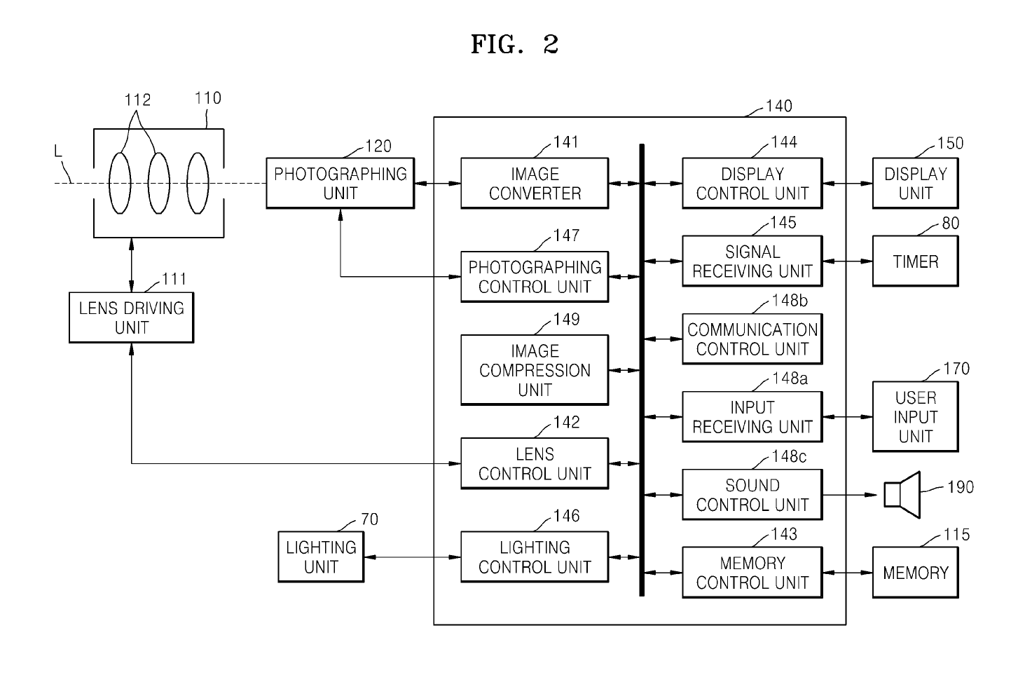

FIG. 2 is a block diagram illustrating components of the mobile electronic device 100 of FIG. 1, according to an embodiment.

A photographing unit 120 is installed in the body 10 of the mobile electronic device 100 of FIG. 1. The photographing unit 120 captures an image of a subject and converts the captured image into an electrical signal. The electrical signal generated by the photographing unit 120 is converted into image data by an image converter 141 of a control unit 140. A photographing control unit 147 of the control unit 140 controls the photographing unit 120 to execute a photographing operation.

The zoom lens barrel 110, which is disposed in front of the photographing unit 120 to form an optical system, includes the plurality of lenses 112 through which image light from an subject passes to form an image on an imaging surface of the photographing unit 120. The zoom lens barrel 110 may be fixed onto the body 10 of the mobile electronic device 100 of FIG. 1 or may be detachably attached to the body 10 when the mobile electronic device 100 is designed as an interchangeable lens type.

The plurality of lenses 112 are arranged so that distances between the lenses 112 may be changeable. When the distances between the lenses 112 are changed, zoom magnification or focus may be adjusted. The lenses 112 are arranged along an optical axis L, which is a virtual straight line passing through optical centers of the lenses 112.

The lenses 112 are driven by a lens driving unit 111 that includes a driving unit, such as a zoom motor (not shown), so as to change locations of the lenses 112 with respect to each other. The lenses 112 may include a zoom lens for magnifying or reducing a size of the subject and a focus lens for focusing the subject.

The lens driving unit 111 receives a control signal from a lens control unit 142 of the control unit 140, and controls locations of the lenses 112 so that the lenses 112 may have one of a plurality of magnifications.

The photographing unit 120 includes a photoelectric conversion device, such as a charge-coupled device (CCD) or a complementary metal-oxide semiconductor (CMOS), to convert the subject's image light incident through the lenses 112 into an electric signal. The photographing unit 120 is driven in response to a control signal applied from the photographing control unit 147.

The image converter 141 converts the electric signal of the photographing unit 120 into image data so as to perform an image process or to store the image data in a storage medium, such as a memory 115. For example, the image converter 141 converts the electric signal of the photographing unit 120 into red (R), green (G), and blue (B) data, and then, may convert the RGB data into raw data, such as a YUV signal including a brightness (Y) signal and a color difference (UV) signal.

In addition, conversion processes of the electric signal of the photographing unit 120 by the image converter 141 may include sub-processes, for example, reducing driving noise of the photographing unit 120 included in the electric signal by using a correlated double sampling (CDS) circuit, adjusting gain of the electric signal after the noise reduction by using an automatic gain control (AGC) circuit, converting an analog signal into a digital signal by using an analog/digital (A/D) converter, pixel defect correction, gain correction, and gamma correction of the digital signal. The CDS circuit, the AGC circuit, or the A/D converter may be configured as additional circuits.

The control unit 140 is electrically connected to the photographing unit 120, the lens driving unit 111, a display unit 150, a timer 80, a user input unit 170, the memory 115, and the lighting unit 70, and transmits or receives controls signals to or from the components to control operations of the components or processes data.

The control unit 140 includes the image converter 141, the lens control unit 142, a memory control unit 143, a display control unit 144, a signal receiving unit 145, a lighting control unit 146, the photographing control unit 147, an input receiving unit 148a, a communication control unit 148b, a sound control unit 148c, and an image compression unit 149.

The control unit 140 may be formed as a micro chip, or a circuit board including a micro chip. In addition, components of the control unit 140 may be realized by software or circuits included in the control unit 140.

The memory control unit 143 controls recording of data in the memory 115 and reading of the recorded data or setting information from the memory 115.

The memory 115 may be a volatile built-in memory, for example, may be formed of a semiconductor memory device, such as a synchronous dynamic random access memory (SDRAM). The memory 115 may function as a buffer memory that temporarily stores the image data generated by the image converter 141 and an operation memory used to process data.

The memory 115 may be a non-volatile external memory, for example, a flash memory such as a memory stick, a secured digital (SD)/multimedia card (MMC), a storage apparatus, such as a hard disk drive (HDD), or an optical storage apparatus, such as a digital versatile disc (DVD) or a compact disc (CD). In the memory 115, image data that is compressed and converted into a format such as a Joint Photographic Experts Group (JPEG) file, a tagged image file (TIF) file, a graphics interchange format (GIF) file, or a PC paintbrush (PCX) file may be stored.

The display unit 150 that displays the image data may be disposed in the back of the body 10 illustrated in FIG. 1. The display unit 150 may be formed as a display device, such as a liquid crystal display (LCD) or an organic light-emitting diode (OLED) display. In addition, a touch screen that senses touches on a surface thereof and generates signals corresponding to sensed locations may be disposed on a surface of the display unit 150.

The user input unit 170 is a part that generates a signal by an operation of a user, such as a shutter button or a menu operation button. The control unit 140 receives a signal of the user input unit 170 through the input receiving unit 148a of the control unit 140 and may use the signal to control the other components of the mobile electronic device 100.

The timer 80 informs a replacement time of the aroma capsule 50 of FIG. 1. For example, the timer 80 is reset when replacing the aroma capsule 50 and may generate a signal informing a period elapse when a period corresponding to a lifespan of the aroma capsule 50 has elapsed. The control unit 140 may inform a user that the aroma capsule 50 needs to be replaced by receiving the signal generated from the timer 80 through the signal receiving unit 145.

The control unit 140 may inform a user of a replacement time of the aroma capsule 50 by displaying image or text information on the display unit 150 or may inform a user of a replacement time by adjusting intensity or color of a light that is radiated by the lighting unit 70.

Embodiments are not limited to the configuration in which, as stated above, the control unit 140 and the timer 80 are connected to each other. For example, the timer 80 may not be connected to the control unit 140 and may perform an independent operation independent of the control unit 140. When a user resets the timer 80 at a time when the aroma capsule 50 is replaced, the timer 80 may warn the user by generating a sound or radiating a light when a period corresponding to a lifespan of the aroma capsule 50 has elapsed.

The lighting control unit 146 controls a light of the lighting unit 70. For example, the lighting control unit 146 may control the amount of light that is radiated from the lighting unit 70 or may control a color of the light.

The communication control unit 148b controls a communication between the mobile electronic device 100 and an external device (not shown). For example, the communication control unit 148b may control a wired communication using a connector, or may control a wireless communication, such as Bluetooth or WiFi.

A sound generation unit 190 may produce a sound when a signal is applied from the sound control unit 148c to the sound generation unit 190. For example, when a signal informing a period corresponding to a lifespan of the aroma capsule 50 is generated by the timer 80, the sound generation unit 190 may generate a voice or specific sound signal to warn a user.

In addition, the sound generation unit 190 may produce a sound having a frequency of a predetermined range that insects dislike. Although insects may gather around the mobile electronic device 100 according to a kind of aroma of the aroma capsule 50, insects can be eradicated by a sound from the sound generation unit 190 at a frequency that insects dislike.

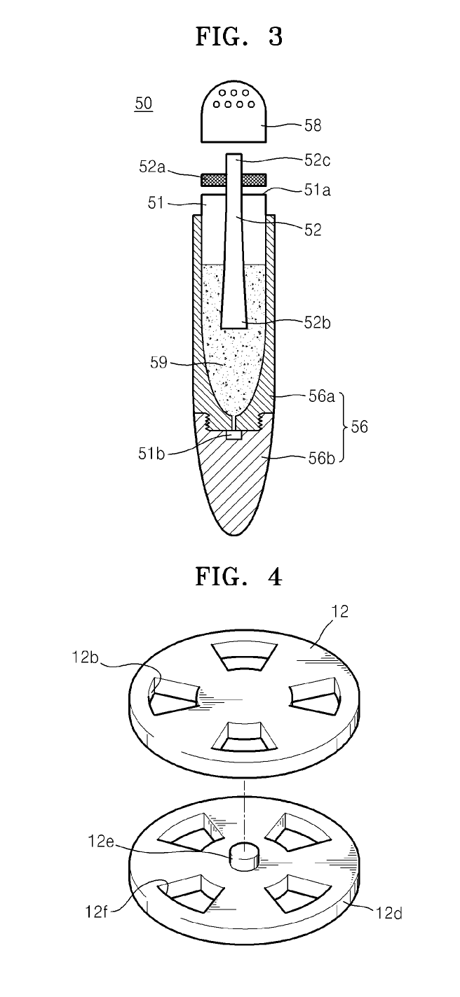

FIG. 3 is a side cross-sectional view illustrating a configuration of the aroma capsule 50 that is installed in the mobile electronic device 100 of FIG. 1, according to an embodiment.

The aroma capsule 50 includes a container 51 which includes an opening 51a and in which an aroma 59 is accommodated, a rod 52 which is inserted in the container 51 and diffuses a fragrance, and a stopper 58 which covers the opening 51a of the container 51.

A capsule support unit 56 is coupled to one side of the container 51. The capsule support unit 56 functions as a supporter that couples the aroma capsule 50 to the mobile electronic device 100 of FIG. 1. The capsule support unit 56 includes a main support unit 56a that is coupled to an outside edge of the container 51 and a filling stopper 56b that is separably coupled to an end portion of the main support unit 56a. If the filling stopper 56b is separated from the main support unit 56a, a filling inlet 51b of the container 51 is exposed to the outside. The aroma 59 can be injected into the inside of the container 51 through the filling inlet 51b.

The aroma 59 may include a material having a liquid or gel state, and one end 52b of the rod 52 is connected with the aroma 59 and the other end 52c of the rod 52 is projected to the outside. The rod 52 may include a wing unit 52a extending along a circumference direction of the rod 52 so as to correspond to the opening 51a of the container 51.

The aroma capsule 50 having the above configuration may diffuse a fragrance of the aroma 59 to the outside via the rod 52 contacting the aroma 59 accommodated in the container 51.

When a user wishes to replace the current fragrance with a different fragrance, the current aroma capsule 50 of the mobile electronic device 100 can be simply replaced with another aroma capsule having a different kind of aroma. In addition, the aroma 59 does not leak since the aroma 59 is stably accommodated inside the compact aromatic capsule 50.

FIG. 4 illustrates the cover 12 that is installed in the mobile electronic device 100 of FIG. 1, according to an embodiment.

An opening control plate 12d is rotatably installed via a rotatable axle 12e at one side of the cover 12 that is installed on the accommodation space 11 of the mobile electronic device 100 of FIG. 1. The opening control plate 12d includes an opening hole 12f that corresponds to the opening hole 12b of the cover 12. The opening control plate 12d adjusts an opening area of the opening hole 12b of the cover 12. By rotating the opening control plate 12d to change the opening area of the opening hole 12b, a user may adjust the intensity of a fragrance of the aroma capsule 50 that is diffused through the opening hole 12b. When the opening hole 12b is aligned with the opening hole 12f to form an opening area in the opening hole 12b, the fragrance of the aroma capsule 50 is diffused. When the opening hole 12b is misaligned with the opening hole 12f so that there is no opening area in the opening hole 12b, the fragrance of the aroma capsule 50 is not diffused.

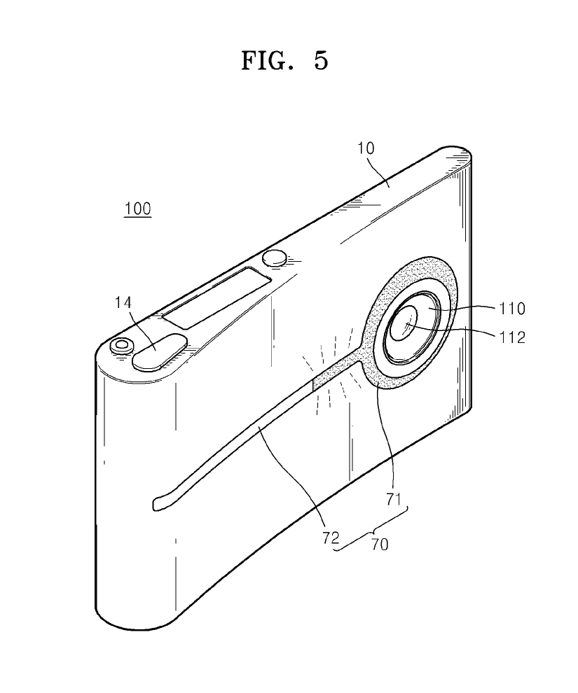

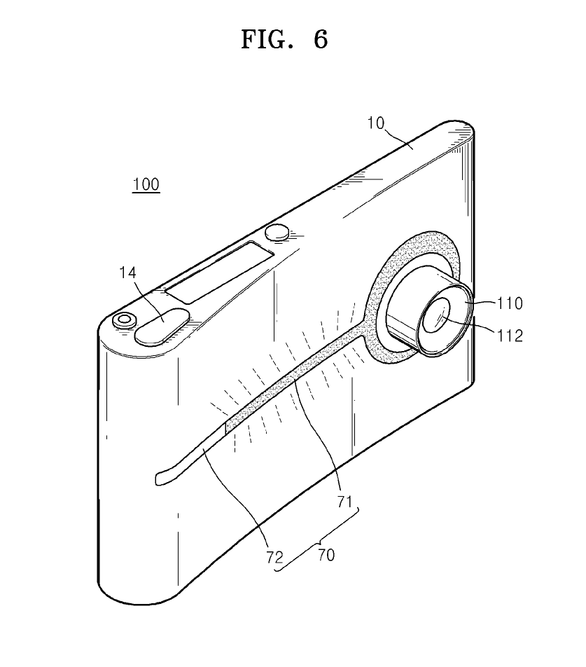

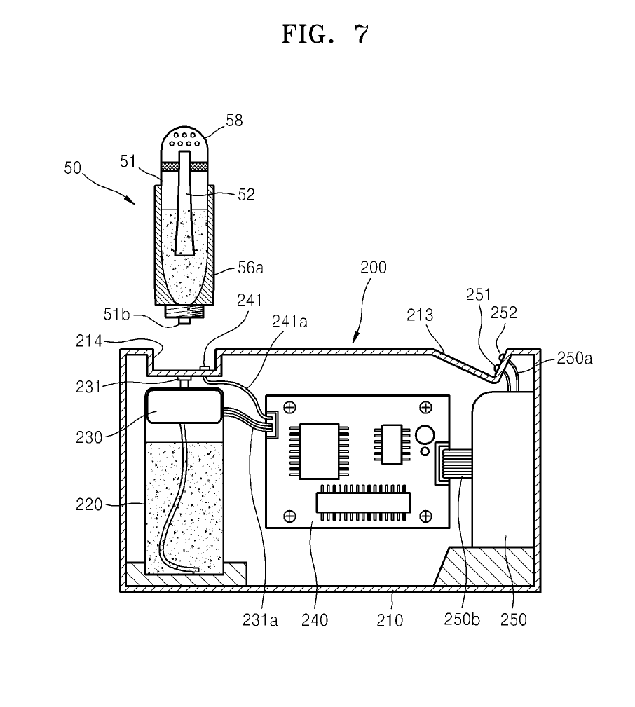

FIG. 5 is a perspective view illustrating an example of an operation of the mobile electronic device 100 of FIG. 1 and FIG. 6 is a perspective view illustrating another example of an operation the mobile electronic device 100 of FIG. 1.

By controlling a light, which the lighting unit 70 radiates, in interaction with an operation of the zoom lens barrel 110 of the mobile electronic device 100, a user who operates the zoom lens barrel 110 finds it convenient. That is, it is possible to change a light of the lighting unit 70 according to a change of a distance to which the zoom lens barrel 110 is projected from the body 10 by operation of the zoom lens barrel 110.

For example, as in FIG. 5, it is possible to minimize a length of an illumination part of the straight unit 72 of the lighting unit 70 when the zoom lens barrel 110 is inserted in the body 10, and, it is possible to increase a length of an illumination part of the straight unit 72 as the zoom lens barrel 110 is projected from the body 10. In addition, as in FIG. 6, it is possible to maximize an illumination part of the straight unit 72 when the zoom lens barrel 110 is projected at a maximum from the body 10.

A method of controlling an operation of the zoom lens barrel 110 and a light of the lighting unit 70 are not limited to the method stated above. For example, it is possible to change the intensity of a light of the lighting unit 70 or change a color of the light of the lighting unit 70.

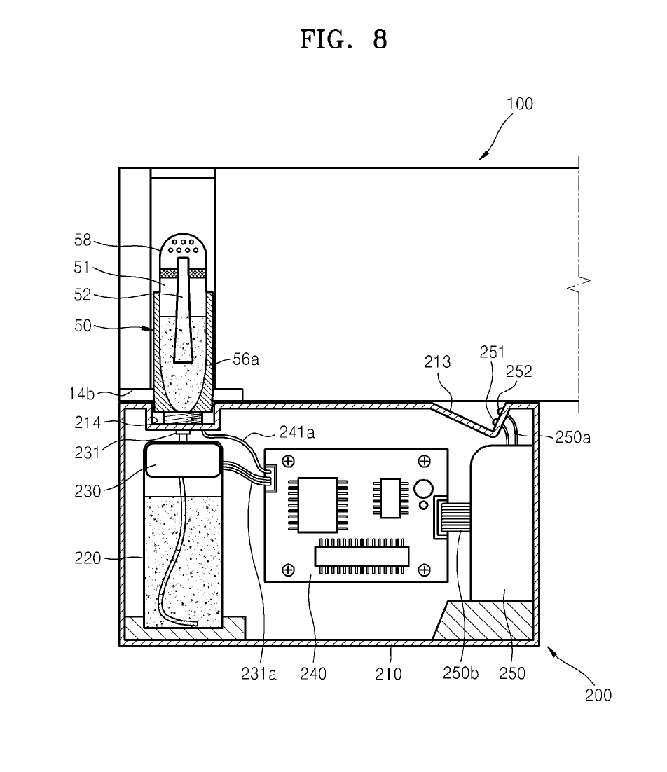

FIG. 7 is a side cross-sectional view illustrating a configuration of a docking station 200 for the mobile electronic device 100 of FIG. 1, according to an embodiment.

Referring to FIG. 7, the docking station 200 includes an aroma storage unit 220 in which an aroma is stored, and an outlet 231 which is connected to the aroma storage unit 220 and through which the aroma is discharged to the outside.

The aroma storage unit 220 may be fixed inside of a case 210. An automatic pump device 230 that discharges the aroma of the aromatic storage unit 220 to the outlet 231 may be installed in the case 210.

The automatic pump device 230 may be electrically connected to a station control unit 240 installed in the case 210 through a wiring 231a and may be controlled by the station control unit 240.

In the outside of the case 210, the fill port 214 is installed in a location corresponding to the outlet 231 of the aroma storage unit 220. When the aroma capsule 50 is inserted into the fill port 214, the filling inlet 51b of the aroma capsule 50 is connected with the outlet 231 of the aroma storage unit 220. Thus, the aroma of the aromatic storage unit 220 that is discharged by operation of the automatic pump device 230 may be injected to the aroma capsule 50.

The contact switch 241 that is electrically connected with the station control unit 240 through the wiring 241a is installed in the fill port 214. When the aroma capsule 50 is installed in the fill port 214, the contact switch 241 recognizes this installation, and thus, the station control unit 240 operates the automatic pump device 230 so that an operation of filling an aroma into the aroma capsule 50 may be automatically performed.

Although, in the current embodiment, the filling operation is performed by using the automatic pump device 230, this should not be construed as limiting. For example, it is possible to discharge an aroma stored in the aroma storage unit 220 through the outlet 231 by installing a hand pump device in the case 210 and manually operating the hand pump device.

FIG. 8 is a side cross-sectional view illustrating an operation state of the docking station 200 of FIG. 7, according to an embodiment.

If a lid 14 coupled to an upper part of the body 10 illustrated in FIG. 5 is removed to expose a lid recess area 14b, a part of the aroma capsule 50 may be projected from the body 10 as illustrated in FIG. 8. It is possible to connect the aroma capsule 50 to the port 214 for filling of the docking station 200 by removing the filling stopper 56b illustrated in FIG. 3 from the aroma capsule 50.

Thus, as illustrated in FIG. 8, it is possible to fill the aroma capsule 50 located inside the mobile electronic device 100 by coupling the mobile electronic device 100 to the case 210 of the docking station 200.

The docking station 200 may include a charging unit 250 that charges the mobile electronic device 100. The charging unit 250 may be electrically connected with the station control unit 240 through a wiring 250b. Terminals 251 and 252, which are connected to the charging unit 250 through the wiring 250a, for charging are installed on the case 210. An installation groove 213 in which the mobile electronic device 100 is installed to charge a battery is formed in the case 210.

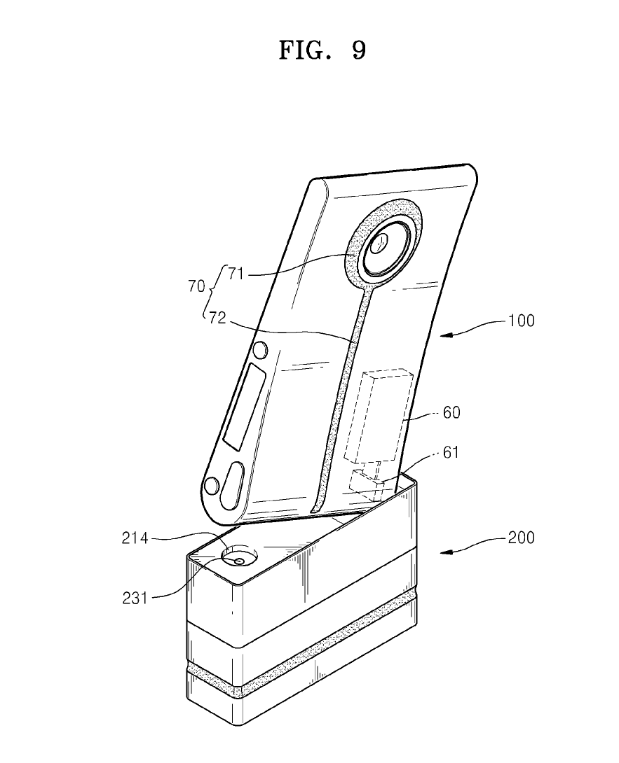

FIG. 9 is a perspective view illustrating an example of an operation of the docking station 200 of FIG. 7.

FIG. 9 illustrates an example of an operation in which the mobile electronic device 100 is coupled to the docking station 200 to charge a battery 60 of the mobile electronic device 100. The mobile electronic device 100 includes the battery 60 and a charging connector 61 that electrically connects the battery 60 with the docking station 200. As illustrated in FIG. 9, when the mobile electronic device 100 is coupled to the docking station 200, the battery 60 of the mobile electronic device 100 may be charged by the docking station 200.

It is convenient for a user to control a light of the lighting unit 70 during a charging operation of the mobile electronic device 100. For example, it is possible to control a length of an illumination part of the straight unit 72 of the lighting unit 70 so as to indicate the amount of battery charge of the mobile electronic device 100.

A length of an illumination part of the straight unit 72 may be decreased since the amount of battery charge is small at the beginning when the mobile electronic device 100 is installed in the docking station 200. The length of the illumination part of the straight unit 72 may be increased as the amount of battery charge of the mobile electronic device 100 increases, and a light may be radiated from the whole area of the straight unit 72 when the mobile electronic device 100 is fully charged. Thus, a user may easily confirm a charging state of the mobile electronic device 100 through a shape of a light that is radiated from the lighting unit 70.

A method of controlling a battery charging operation and a light of the lighting unit 70 are not limited to the method stated above. For example, various methods, such as changing the intensity of a light of the lighting unit 70, changing a color of the light of the lighting unit 70, or changing an illumination area of the ring unit 71 of the lighting unit 70, may be used.

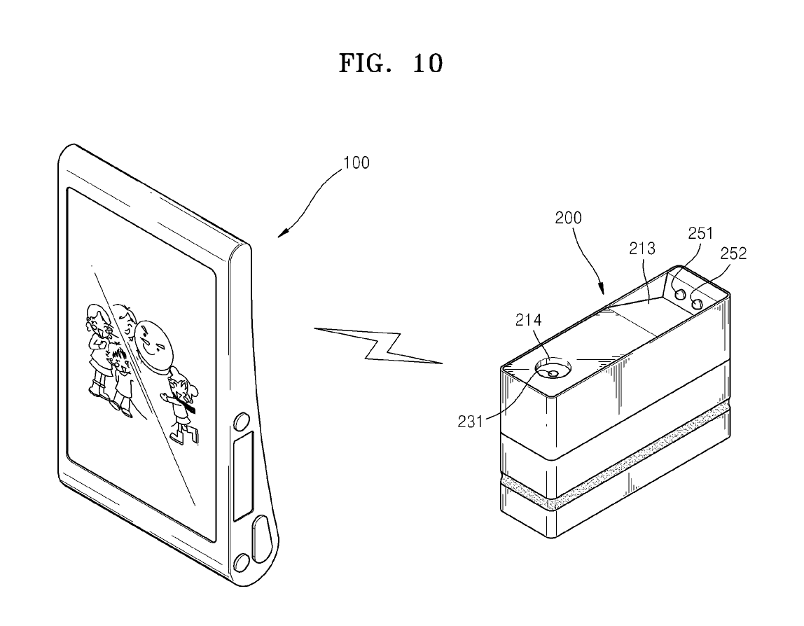

FIG. 10 is a perspective view illustrating another example of an operation of the docking station 200 of FIG. 7.

FIG. 10 illustrates an example of an operation in which a wireless communication is performed between the mobile electronic device 100 and the docking station 200. The docking station 200 may include a communication unit (not shown) that performs a wireless communication between the mobile electronic device 100 and the docking station 200. In addition, the station control unit 240 may include a data storage unit (not shown) that stores data received from the mobile electronic device 100 by wireless communication.

Through the wireless communication, a still image or moving image stored in the mobile electronic device 100 may be automatically transmitted or stored in the docking station 200, and an operation of deleting data of the mobile electronic device 100 may be automatically performed after the transmitting or storing operation.

In addition, through the wireless communication, a still image or moving image stored in the docking station 200 may be automatically transmitted to the mobile electronic device 100, and an operation such as seeing a movie or editing may be performed in the mobile electronic device 100.

A communication between the mobile electronic device 100 and the docking station 200 is not limited to the wireless communication stated above, and it is possible to use a wired communication between the mobile electronic device 100 and the docking station 200 through a communication line.

All references, including publications, patent applications, and patents, cited herein are hereby incorporated by reference to the same extent as if each reference were individually and specifically indicated to be incorporated by reference and were set forth in its entirety herein.

For the purposes of promoting an understanding of the principles of the invention, reference has been made to the embodiments illustrated in the drawings, and specific language has been used to describe these embodiments. However, no limitation of the scope of the invention is intended by this specific language, and the invention should be construed to encompass all embodiments that would normally occur to one of ordinary skill in the art. The terminology used herein is for the purpose of describing the particular embodiments and is not intended to be limiting of exemplary embodiments of the invention. In the description of the embodiments, certain detailed explanations of related art are omitted when it is deemed that they may unnecessarily obscure the essence of the invention.

The apparatus described herein may comprise a processor, a memory for storing program data to be executed by the processor, a permanent storage such as a disk drive, a communications port for handling communications with external devices, and user interface devices, including a display, touch panel, keys, buttons, etc. When software modules are involved, these software modules may be stored as program instructions or computer readable code executable by the processor on a non-transitory computer-readable media such as magnetic storage media (e.g., magnetic tapes, hard disks, floppy disks), optical recording media (e.g., CD-ROMs, Digital Versatile Discs (DVDs), etc.), and solid state memory (e.g., random-access memory (RAM), read-only memory (ROM), static random-access memory (SRAM), electrically erasable programmable read-only memory (EEPROM), flash memory, thumb drives, etc.). The computer readable recording media may also be distributed over network coupled computer systems so that the computer readable code is stored and executed in a distributed fashion. This computer readable recording media may be read by the computer, stored in the memory, and executed by the processor.

Also, using the disclosure herein, programmers of ordinary skill in the art to which the invention pertains may easily implement functional programs, codes, and code segments for making and using the invention.

The invention may be described in terms of functional block components and various processing steps. Such functional blocks may be realized by any number of hardware and/or software components configured to perform the specified functions. For example, the invention may employ various integrated circuit components, e.g., memory elements, processing elements, logic elements, look-up tables, and the like, which may carry out a variety of functions under the control of one or more microprocessors or other control devices. Similarly, where the elements of the invention are implemented using software programming or software elements, the invention may be implemented with any programming or scripting language such as C, C++, JAVA®, assembler, or the like, with the various algorithms being implemented with any combination of data structures, objects, processes, routines or other programming elements. Functional aspects may be implemented in algorithms that execute on one or more processors. Furthermore, the invention may employ any number of conventional techniques for electronics configuration, signal processing and/or control, data processing and the like. Finally, the steps of all methods described herein may be performed in any suitable order unless otherwise indicated herein or otherwise clearly contradicted by context.

For the sake of brevity, conventional electronics, control systems, software development and other functional aspects of the systems (and components of the individual operating components of the systems) may not be described in detail. Furthermore, the connecting lines, or connectors shown in the various figures presented are intended to represent exemplary functional relationships and/or physical or logical couplings between the various elements. It should be noted that many alternative or additional functional relationships, physical connections or logical connections may be present in a practical device. The words “mechanism”, “element”, “unit”, “structure”, “means”, and “construction” are used broadly and are not limited to mechanical or physical embodiments, but may include software routines in conjunction with processors, etc.

The use of any and all examples, or exemplary language (e.g., “such as”) provided herein, is intended merely to better illuminate the invention and does not pose a limitation on the scope of the invention unless otherwise claimed. Numerous modifications and adaptations will be readily apparent to those of ordinary skill in this art without departing from the spirit and scope of the invention as defined by the following claims. Therefore, the scope of the invention is defined not by the detailed description of the invention but by the following claims, and all differences within the scope will be construed as being included in the invention. No item or component is essential to the practice of the invention unless the element is specifically described as “essential” or “critical”. It will also be recognized that the terms “comprises,” “comprising,” “includes,” “including,” “has,” and “having,” as used herein, are specifically intended to be read as open-ended terms of art. The use of the terms “a” and “an” and “the” and similar referents in the context of describing the invention (especially in the context of the following claims) are to be construed to cover both the singular and the plural, unless the context clearly indicates otherwise. In addition, it should be understood that although the terms “first,” “second,” etc. may be used herein to describe various elements, these elements should not be limited by these terms, which are only used to distinguish one element from another. Furthermore, recitation of ranges of values herein are merely intended to serve as a shorthand method of referring individually to each separate value falling within the range, unless otherwise indicated herein, and each separate value is incorporated into the specification as if it were individually recited herein.

What is claimed is:

1. A mobile electronic device comprising:
a body including an accommodation space; and
an aroma capsule that is accommodated in the accommodation space, is removable from the accommodation space, and includes an aroma to diffuse a fragrance.

2. The mobile electronic device of claim 1, further comprising:
a lighting unit that is disposed on the outside of the body and radiates light as a signal is applied thereto; and
a control unit that is disposed in the body and applies the signal to the lighting unit to control the lighting unit.

3. The mobile electronic device of claim 2, further comprising:
a timer that informs a replacement time of the aroma capsule when a predetermined time has elapsed after replacing the aroma capsule.

4. The mobile electronic device of claim 2, wherein the control unit controls an amount of light that is radiated by the lighting unit.

5. The mobile electronic device of claim 2, wherein the lighting unit is formed to extend by a predetermined length along a surface of the body, and the control unit changes a length of an illumination part of the lighting unit.

6. The mobile electronic device of claim 2, wherein the control unit changes a color of the light that is radiated by the lighting unit.

7. The mobile electronic device of claim 1, further comprising:
a cover that is coupled to the body to cover the accommodation space.

8. The mobile electronic device of claim 7, wherein the cover comprises an opening hole of which an opening area is adjusted.

9. The mobile electronic device of claim 1, wherein the aroma capsule comprises:
a container with an opening, the container having an aroma therein;
a rod that is inserted in the container through the opening so that a part of the rod contacts the aroma and diffuses a fragrance; and
a stopper that covers the opening of the container.

10. The mobile electronic device of claim 2, further comprising:
a zoom lens barrel that is disposed in the body and is operable to be projected from the body,
wherein the control unit changes a light of the lighting unit according to a projected length of the zoom lens barrel from the body.

11. The mobile electronic device of claim 2, further comprising:
a sound generation unit that generates a sound,
wherein the control unit controls the sound generation unit to generate a sound having a frequency of a predetermined range that insects dislike.

12. A docking station for a mobile electronic device, the docking station comprising:
an aroma storage unit that stores an aroma; and
an outlet that is connected to the aroma storage unit and discharges the aroma of the aroma storage unit to the outside.

13. The docking station of claim 12, further comprising:
a hand pump device that discharges the aroma of the aroma storage unit to the outlet through a manual manipulation.

14. The docking station of claim 12, further comprising:
an automatic pump device that discharges the aroma of the aroma storage unit to an aroma capsule through the outlet when a signal is applied to the automatic pump device after the aroma capsule is connected to the outlet.

15. The docking station of claim 12, further comprising:
a communication unit that communicates with the mobile electronic device;
a data storage unit that stores data that is received from the mobile electronic device through the communication unit; and
a station control unit that is electrically connected to the communication unit and the data storage unit and controls the communication unit and the data storage unit.

16. The docking station of claim 12, further comprising:
a charging unit that is electrically connected with the mobile electronic device and charges the mobile electronic device.
